(19) United States
(12) Patent Application Publication
(10) Pub. No.: US 2024/0266799 A1
(43) Pub. Date: Aug. 8, 2024

(54) Semiconductor Laser and Optical Transmitter

(71) Applicant: Nippon Telegraph and Telephone Corporation, Tokyo (JP)

(72) Inventors: Meishin Chin, Musashino-shi, Tokyo (JP); Takahiko Shindo, Musashino-shi, Tokyo (JP); Shigeru Kanazawa, Musashino-shi, Tokyo (JP)

(21) Appl. No.: 18/567,260

(22) PCT Filed: Jun. 14, 2021
(86) PCT No.: PCT/JP2021/022486

§ 371 Date: Dec. 5, 2023

(51) Int. Cl. H01S 5/026; H01S 5/10; H01S 5/50

(52) U.S. Cl. CPC H01S 5/0265; H01S 5/1014; H01S 5/50

(57) ABSTRACT

A problem is addressed by suppressing a decrease in a laser output due to an optical axis deviation between a laser portion waveguide and an EA portion waveguide in a semiconductor laser. The configuration of the present invention has a structure in which a spot size converter of a passive waveguide is integrated between a laser and an EA of an EADFB laser. A feature of the spot size converter is a configuration having an enlarged taper/a straight waveguide/a reduced taper, in which aspect ratios of the tapers are the same. Further, by providing the spot size converter between an EA and an SOA (Semiconductor Optical Amplifier), it is possible to apply the spot size converter to an AXEL (semiconductor optical Amplifier extended reach EA-DFB).

### TECHNICAL FIELD

The present invention relates to a semiconductor laser, and more particularly to a semiconductor laser in which an EA modulator and a semiconductor laser are monolithically integrated into one semiconductor chip.

### BACKGROUND ART

This type of semiconductor laser is generally called an Electron-Absorption Distributed Feed Back: EADFB laser, and implements switching between ON and OFF of light by quenching a laser beam with a modulator which absorbs the laser beam from the semiconductor laser which continues to emit light at a constant intensity. The semiconductor laser according to this system has advantages such as obtaining of a high extinction ratio and a small change in an optical wavelength during the modulation, that is, a low chirp characteristic. FIGS. 1 (a) and (b) are diagrams schematically showing the configuration of the EADFB laser, and FIG. 1 (b) shows a cross section taken along the line 1 b-1 b of FIG. 1 (a). As shown in these figures, the EADFB laser 10 includes a laser portion 11 configured to have an active layer 111 and an upper cladding layer 112 formed on a substrate 13, and a modulation (EA) portion 12 configured to have an absorption layer and an upper cladding layer that are not shown respectively. By the way, the structure of the laser portion 11 shown in FIG. 1 is a form in which the substrate 13 under the active layer 111 also serves a function as a lower cladding layer. In addition, similarly in the EA portion 12, the substrate 13 under the absorption layer also serves a function as a lower cladding layer. An embedded portion 14 made of an insulating material is formed on the substrate 13 so as to embed the laser portion 11 and the EA portion 12.

Further, a hybrid waveguide structure is used for the purpose of performing ON/OFF of light at a high speed in the semiconductor laser (Non Patent Literature 1). This is the hybrid structure in which the only EA portion has a mesa stripe shape, with the embedded portion being removed, while the laser portion has the embedded portion. Thus, an increase of a parasitic capacitance which can occur in the embedded portion is suppressed, and the reduction of the cut-off frequency in a frequency characteristic of the EA portion is prevented.

FIGS. 2 (a) to 2 (d) are diagrams illustrating the forming of the conventional EADFB laser described above with reference to FIG. 1. First, the active layer 111 of the laser section 11 is grown on the substrate 13 (InP wafer). Then, a part (end part) thereof is removed by an etching treatment, and the absorption layer 121 of the EA portion 12 is joined to the active layer 111 on the same plane of the substrate 13 so as to integrate by a technique called a butt joint (FIG. 2 (a)). Thereafter, the cladding layer (not shown) having a low refractive index is laminated on the entire surface of the substrate 13 so as to confine light with the active layer 111 and the absorption layer 121 in a direction perpendicular to the substrate 13. Next, waveguide structures (111, 121) for confining the light in the horizontal direction with respect to the substrate 13 and uniformly guiding the light in a specific direction are formed in a mesa stripe shape by the etching (FIG. 2 (b)). Further, both sides of the mesa stripe waveguides (111, 121) are filled with an insulating semiconductor material (Fe-doped InP or the like) having a thermal conductivity higher than that of air (FIG. 2 (c)). Finally, removing the embedded portion 14 from the only EA portion 12 (FIG. 2 (d)), the EADFB laser is formed. In the EADFB laser formed as described above, a diffraction grating where a refractive index periodically changes is formed in the cladding region that is upper layer than the active layer of the laser portion 11, and an oscillation wavelength is determined. When viewed from the top like this, the laser in which the active layer and the diffraction grating are formed in the same region is known as a DFB laser. The active layer 111 of the laser portion and the absorption layer 121 of the EA portion 12 are generally a multi-quantum-well (MQW). In the EA modulator (12) integrated with the DFB laser (11), since a wavelength of an absorption spectrum approaches the laser wavelength according to an applied voltage through a quantum confined Stark effect, an electric signal can be converted into an ON/OFF signal of an optical signal by changing amount of the light absorption through the voltage control.

### CITATION LIST

### Non Patent Literature

[NPL 1] Yojiro Watanabe, Norio Okada, Yusuke Azuma, and Tatuki Otani, “25 Gbps CAN type EML for 5G Mobile Base Stations”, Mitsubishi Electric Technical Report, March 2019, Vo. 93, No. 03
[NPL 2] W Kobayashi et al., “Novel approach for chirp and output power compensation applied to a 40-Gbit/s EADFB laser integrated with a short SOA,” Opt. Express, April 2015, Vol. 23, No. 7, pp. 9533-9542

### SUMMARY OF INVENTION

As described above, when the laser having the hybrid waveguide structure in which the embedded portion is removed from the only EA portion is formed, in the EA portion, the two-times semiconductor etching processes described with reference to FIGS. 2 (b) and 2 (d) are implemented to form the mesa stripe shaped waveguide structure. In this case, in the second processing, since the embedded portion (embedded part) 14 (removed portion 15) is completely removed in the EA portion 12 as shown in FIG. 3 (a), it is desirable to process the EA portion 12 with the same width as the width W1 of the mesa stripe shaped waveguide formed in the first processing and without axial deviation.

However, in consideration of processing accuracy, since it is difficult to implement processing of the same width, actually, as shown in FIG. 3 (b), a mesa stripe shape having a smaller width W2 is processed. Therefore, the width of the mesa waveguide in the EA portion 12 is different from (smaller than) the width of the mesa waveguide in the laser portion. In addition, in consideration of the accuracy of the resist exposure used in processing, it can be considered that the axial deviation may occur. For example, in the case of an ordinary laser for communication, its wavelength is in the range of 1.3 μm to 1.6 μm, and therefore, the width of the waveguide may be in the range of about 0.5 to 5 μm. When the waveguide width of the laser portion 11 is 2 μm and the waveguide width of the EA portion 12 is 1 μm, if an axial deviation of 1 μm occurs in the second processing, the width of the mesa waveguide including the active layer of the EA portion 12 becomes 0.5 μm. As a result, the decrease of the extinction ratio in the EA portion occurs due to a decrease of a coupling coefficient between the propagation mode and the absorption layer. In addition, if there is a change of the waveguide width or an optical axis deviation, a portion 14, failed to be removed in the embedded portion remains in a region of the width W2 as shown in FIG. 3 (c), a loss in an optical connection is generated between the laser portion and the EA portion by this influence, and the output of the semiconductor laser may be reduced.

An object of the present invention is to provide a semiconductor laser capable of suppressing a decrease in laser output due to an optical axis deviation between a laser waveguide and an EA waveguide.

One embodiment of the semiconductor laser of the present invention includes: a laser having an active region for injecting a current to generate an optical gain; a modulator for changing an absorption coefficient by applying a voltage; and a spot size converter combining an enlarged taper and a reduced taper, which are monolithically integrated on a same substrate, where the spot size converter is disposed between the laser region of the laser and the absorption region of the modulator.

According to the above-described configuration, it is possible to suppress the decrease in laser output due to the optical axis deviation between the laser waveguide and the EA waveguide in the semiconductor laser.

### BRIEF DESCRIPTION OF DRAWINGS

FIGS. 1 (a) and 1 (b) are diagrams schematically showing configurations of an EADFB laser.

FIGS. 2 (a) to 2 (d) are diagrams illustrating a forming method of a conventional EADFB laser.

FIG. 3 is a diagram illustrating a forming method of an EADFB laser including an SSC of an embodiment 1 of the present invention.

FIG. 4 is a diagram schematically illustrating a main part of an EADFB laser according to an embodiment 1 of the present invention.

FIG. 5 is a diagram illustrating a forming of an EADFB laser including an SSC of an embodiment 1 of the present invention.

FIG. 6 is a diagram showing a state of an EADFB laser when an axial deviation occurs in a second processing of an embodiment 1 of the present Invention.

FIG. 7 is a diagram showing a comparative example.

FIG. 8 is a diagram showing a comparative example.

FIG. 9 is a diagram showing a change in transmission efficiency with respect to an axial deviation.

FIG. 10 is a diagram showing a change in a parasitic capacitance of an EA portion with respect to amount of an axial deviation.

FIG. 11 is a diagram schematically illustrating a main part of an EADFB laser according to an embodiment 2 of the present invention.

FIG. 12 is a diagram illustrating a forming method of an EADFB laser according to an embodiment 2 of the present invention.

### DESCRIPTION OF EMBODIMENTS

Embodiments of the present invention will be described in detail below with reference to the drawings.

### Embodiment 1

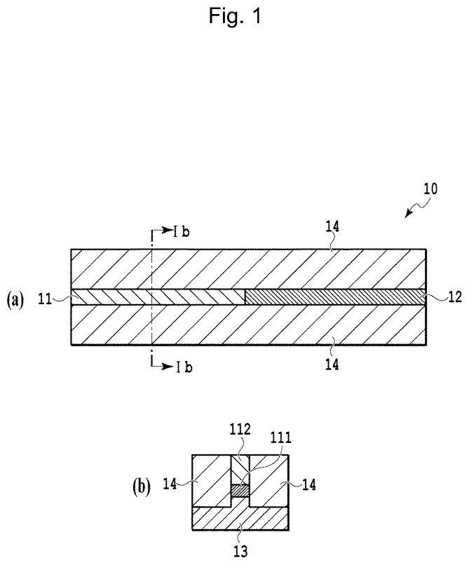

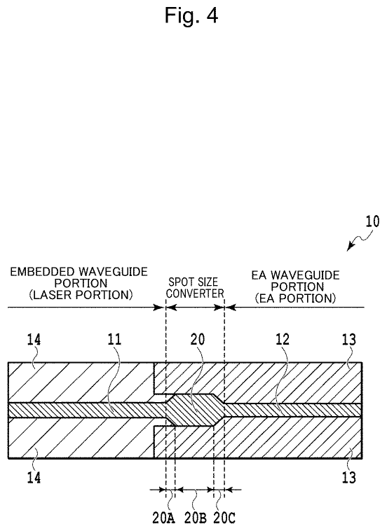

FIG. 4 is a diagram schematically showing a main part of an EADFB laser 10 according to the embodiment of the present invention. The EADFB laser 10 of the present invention has a structure including a spot size converter (SSC) 20 between a laser portion 11 and an EA portion 12 as a waveguide structure. The SSC 20 has a shape having an enlarged tapered portion 20A, a straight portion 20B, and a reduced tapered portion 20C from the laser portion 11 through the EA portion 12. In addition, the SSC 20 is a passive waveguide structure different from the laser portion 11 having an active layer and the EA portion 12 having an absorption layer. Further, as described above, the laser portion 11 is the waveguide embedded by the embedded portion 14, and the EA portion 12 is a mesa waveguide without embedded portion. By the way, the structure of the EADFB laser 10 of this embodiment is the same as the laser portion 11 and the EA portion 12 described above in FIG. 1 except for the SSC 20 described above, and in particular, the substrate 13 under the active layer 111 and the absorption layer 121 also serves a function as a lower cladding layer.

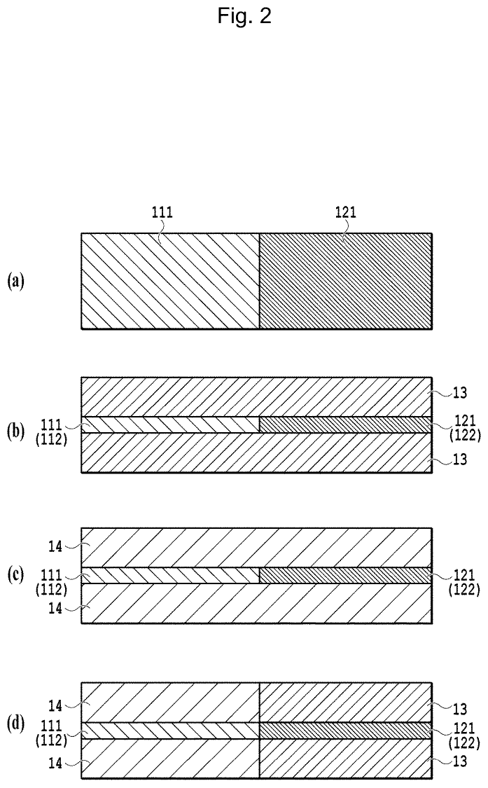

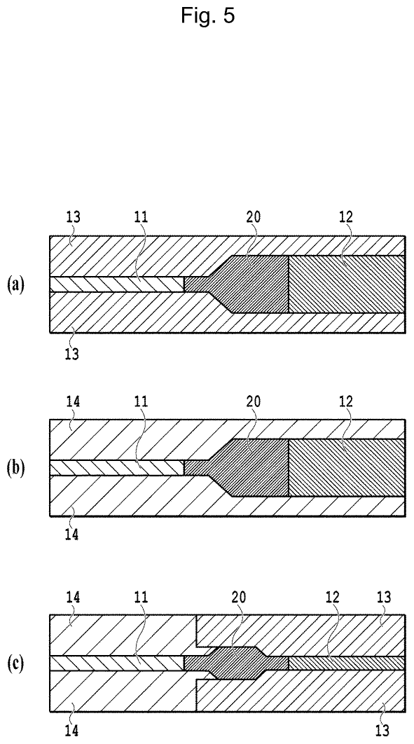

FIG. 5 is a diagram illustrating a forming of an EADFB laser including an SSC of this embodiment. By the way, the forming of the EADFB laser of this embodiment is the same as the forming described in FIG. 2 except for the following points.

First, when the first processing for forming a mesa stripe shape, as shown in FIG. 5 (a), in the stripe shape from the laser portion 11 to the EA portion 12 via the SSC portion 20, an enlarged tapered portion 20A and a straight portion 20B of the SSC portion 20, and the EA portion 12 having a shape with the same width as that of this straight portion are processed. At this time, the enlargement ratio of the enlarged tapered portion 20A is about 1:30 in an aspect ratio. This enlargement ratio can avoid excessive excitation of the high-order mode. As an example, the spread of the waveguide width is about 5 μm while propagating 150 μm. When the width of the mesa waveguide is 2 μm in the laser portion 11 and the length of the enlarged tapered portion 20A is 60 μm, the widths of the mesa waveguides of the SSC portion 20 after enlargement and the EA portion 12 are 6 μm. By the way, in this configuration, the height of the mesa waveguide is 4 μm. Next, as shown in FIG. 5 (b), regions other than the mesa waveguide formed in the above-described process in FIG. 5 (a) are filled with InP doped with Fe, which is an insulating semiconductor material, to form an embedded portion 14. Thereafter, as shown in FIG. 5 (c), the embedded portions 14 in the regions corresponding to the SSC portion 20 and the EA portion 12 are removed, and the second processing for forming the mesa waveguide is performed. At this time, the width of the straight portion 20B of the SSC portion 20 is made small, and a reduced portion 20C is formed, concurrently the width of the mesa waveguide of the EA portion is made equal to the minimum width of the reduced portion 20C. As an example, the width of the straight portion 20B is 4 μm smaller than the width of the straight portion 20B at the first time. In addition, the aspect ratio of the taper of the reduced portion 20C is the same as that of the enlarged tapered portion (enlargement portion) 20A. When the taper length of the reduced portion 20C is 42 μm, the mesa waveguide width of the EA portion 12 becomes 1.2 μm. By the way, in the second processing, since the embedded portion being the semiconductor material is removed, the difference of the refractive indexes of the core (active layer, absorption layer) and the cladding becomes large, thereby the expansion of the light confinement mode in the vertical direction is increased. Therefore, in order to prevent the light radiation to the substrate side, the deeper mesa waveguide than the mesa waveguide processing at the first time is processed. This depth varies depending on the design of the waveguide, but it is normally processed to be 0.1 to 10 μm deeper than the bottom surface of the waveguide formed at the first time. According to this embodiment, it is processed 2 μm deep. By this second processing, the SSC 20 having the enlarged tapered portion and the reduced tapered portion can be formed. By the way, the distance between the tapered portions is determined so that the straight portion 20B between the enlarged tapered portion 20A and the reduced tapered portion 20C is formed at 20 μm or more.

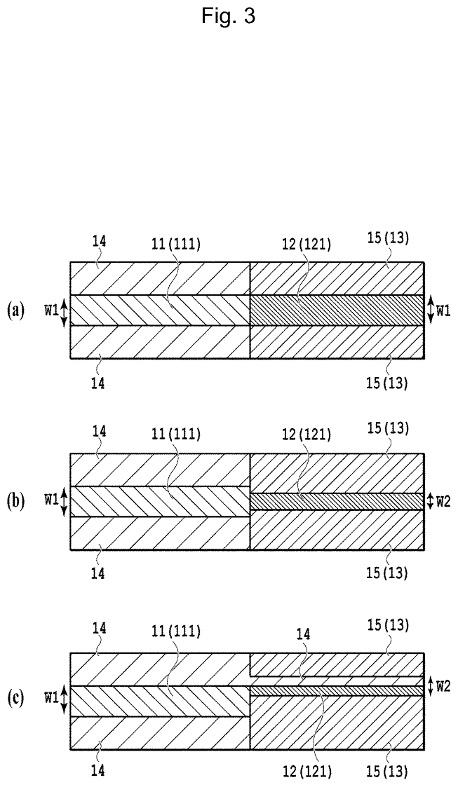

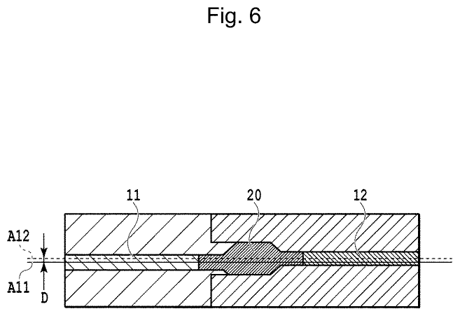

FIG. 6 is a diagram showing a state of the EADFB laser when the axial deviation occurs in the second processing described above in FIG. 5. As shown in the figure, a deviation D occurs between an axis A11 of the laser portion 11 and an axis A12 of the EA portion. This can occur when the embedded portion is removed in the second processing as described above in FIG. 3. In contrast to this, according to the embodiment of the present invention, the SSC portion 20 is provided between the laser portion 11 and the EA portion 12 to improve the tolerance against the deviation D described above. According to the structure of this embodiment, even if an axial deviation of 1 μm occurs, the increase of the optical loss can be suppressed.

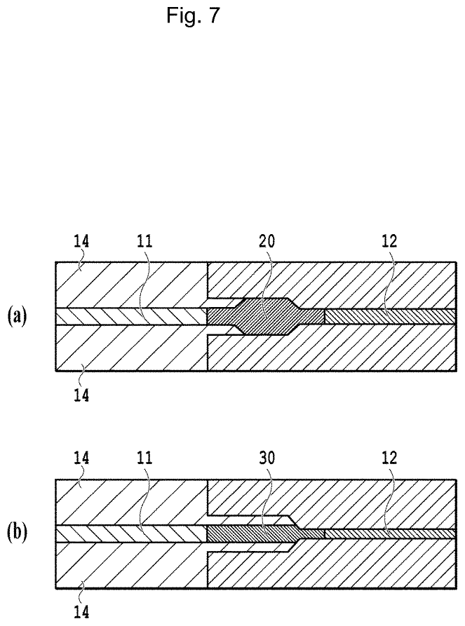

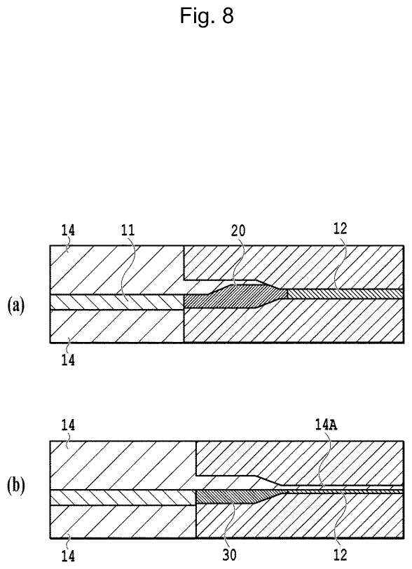

In order to confirm this effect according to the embodiment, the two structures shown in FIG. 7 are compared. In addition, FIG. 8 shows a case where there is an axial deviation in each structure shown in FIG. 7. That is, FIG. 7 (a) shows the laser with the SSC 20 having the enlarged portion and the reduced portion according to this embodiment; FIG. 7 (b) shows the laser with the SSC 30 having the only reduced portion, respectively.

In these structures, as an example, the waveguide width of the laser portion 11 is 2.0 μm, and the waveguide width of the EA portion 12 is 1.2 μm. In these structures, when the axial deviation D with 0.4 μm ((2.0 μm−1.2 μm)/2) or more occurs in the structure having the only reduced taper portion 30, the embedded portion 14 is included in the waveguide of the EA portion 12 as shown in 14A of FIG. 8 (b). Since the embedded portion is the cladding of the waveguide, whose refractive index is lower than that of the waveguide including the absorption layer as the core. As a result, when the axial deviation occurs and the embedded portion is included in the EA portion, the effective refractive index of the absorption layer decreases. Thus, the light confinement is weakened and the loss is increased. Further, since the parasitic capacitance increases in the embedded portion, the CR time constant of the EA portion increases, and the cut-off band decreases. Thus, the frequency response characteristic is deteriorated.

In contrast to this, in the laser structure of this embodiment, the enlarged taper is formed in the first processing, thereby, to enlarge the waveguide width of the EA portion. As a result, in the above example, up to 2.4 μm of the axial deviation D can prevent the embedded portion from being included in the waveguide of the EA portion. By the way, when the axial deviation D is 1 μm or more, the waveguide of the laser portion before the SSC is affected, so that the maximum of the substantially allowable axial deviation D is 1 μm. Also in this case, the tolerance of about two times or more can be realized as compared with the structure having the only reduced tapered portion shown in FIG. 7 (b).

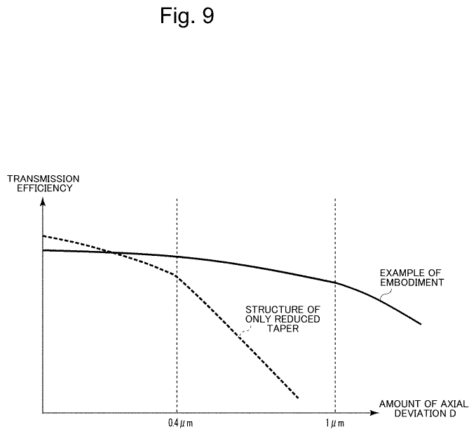

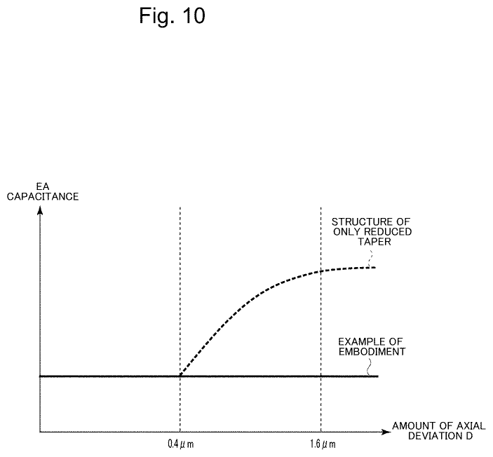

FIG. 9 shows a change in the transmission efficiency with respect to the axial deviation. In the structure having only reduced tapered portion shown in FIG. 7 (b), when there is an axial displacement of 0.4 μm or more, the transmission efficiency decreases remarkably, whereas in the sample structure according to the embodiment, the reduction the in transmission efficiency is suppressed up to 1 μm. In addition, FIG. 10 shows a change in the parasitic capacitance of the EA portion with respect to the amount of the axial deviation. As described above in FIG. 8 (b), the increase of the parasitic capacitance occurs mainly by causing the embedded regions to mix within the waveguide of the EA portion. In particular, zinc of the p-type additive of the waveguide diffuses into the embedded region, thereby the parasitic capacitance of the embedded portion increases remarkably. On this account, since the embedded portion near the waveguide is more affected by the diffusion, its parasitic capacitance is large. As a result, the capacitance increases non-linearly as shown in FIG. 10. In contrast to this, in the example according to this embodiment, if the axial deviation is equal to or less than 2.4 μm, the embedded region does not mix into the EA portion, so that the increase of the parasitic capacitance does not occur.

### Embodiment 2

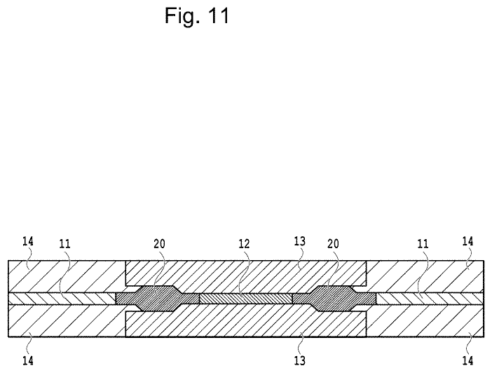

A second embodiment of the present invention will be described with reference to FIG. 11.

FIG. 11 is a diagram schematically showing a main part of the EADFB laser 10 according to the second embodiment of the present invention. The EADFB laser 10 of the present invention has a structure including a plurality of spot size converters (SSC) 20 between a plurality of laser portions 11 and an EA portion 12 as a waveguide structure. Each SSC 20 has a shape, as with the SSC 20 in FIG. 4, including an enlarged tapered potion 20A, a straight portion 20B, and a reduced tapered portion 20 C from the laser portion 11 through the EA portion 12. In addition, the SSC 20 is a passive waveguide structure different from the laser portion 11 having the active layer and the EA portion 12 having the absorption layer. Further, as described above, the laser portion 11 is the waveguide embedded by the embedded portion 14, and the EA portion 12 is a mesa waveguide without embedded portion. By the way, the structure of the EADFB laser 10 of this embodiment is the same as the laser portion 11 and the EA portion 12 described above in FIG. 1 except for the SSC 20 described above, and in particular, the substrate 13 under the active layer 111 and the absorption layer 121 also serves a function as a lower cladding layer.

The output can be increased by integrating the SOA with the EADFB (Non Patent Literature 2). In contrast to this, by including two SSCs (spot size converters) 20 in the configuration, the tolerance of the axial deviation can be enhanced when high-mesa processing the EA portion.

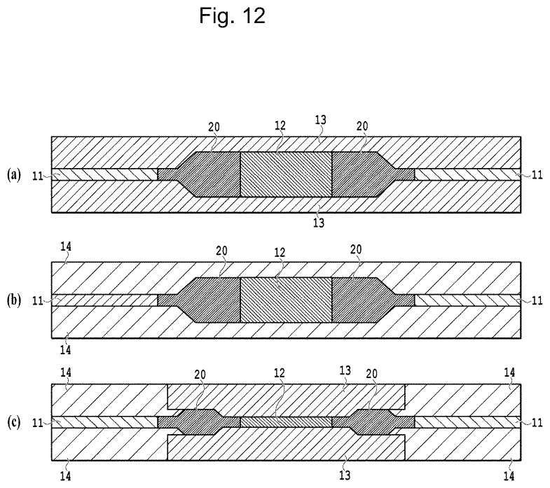

FIG. 12 shows a processing method of an optical transmitter of the embodiment 2. The basic semiconductor process is the same as that of the embodiment 1, however it can be processed by using a photo-mask having a shape different from that of the photo-mask used in the embodiment 1.

FIG. 12 is a diagram illustrating a forming of an EADFB laser 10 including the SSC 20 of this embodiment. By the way, the forming of the EADFB laser of this embodiment is the same as the forming described in FIG. 2 except for the following points.

First, when the processing for forming a mesa stripe shape at the first time, as shown in FIG. 12 (a), in the stripe shape from the laser portion 11 to the EA portion 12 via the SSC portion 20, an enlarged tapered portion 20A and a straight portion 20B of the SSC portion 20, and the EA portion 12 having a shape with the same width as that of this straight portion are processed. At this time, the enlargement ratio of the enlarged tapered portion 20A is about 1:30 in aspect ratio. This enlargement ratio can avoid excessive excitation of the high-order mode. As an example, the spread of the waveguide width is about 5 μm while propagating 150 μm. When the width of the mesa waveguide is 2 μm in the laser portion 11 and the length of the enlarged tapered portion 20A is 60 μm, the widths of the mesa waveguides of the SSC portion 20 after enlargement and the EA portion 12 are 6 μm. By the way, in this configuration, the height of the mesa waveguide is 4 μm. Next, as shown in FIG. 5 (b), regions other than the mesa waveguide formed in the above-described process in FIG. 5 (a) are filled with InP doped with Fe, which is an insulating semiconductor material, to form an embedded portion 14. Thereafter, as shown in FIG. 5(c), the embedded portions 14 in the regions corresponding to the SSC portion 20 and the EA portion 12 are removed, and the second processing for forming the mesa waveguide is performed. At this time, the width of the straight portion 20B of the SSC portion 20 is made small, and a reduced portion 20C is formed, concurrently the width of the mesa waveguide of the EA portion is made equal to the minimum width of the reduced portion 20C. As an example, the width of the straight portion 20B is 4 μm smaller than the width of the straight portion 20B at the first time. In addition, the aspect ratio of the taper of the reduced portion 20C is the same as that of the enlarged tapered portion (enlargement portion) 20A. When the taper length of the reduced portion 20C is 42 μm, the mesa waveguide width of the EA portion 12 becomes 1.2 μm. By the way, in the second processing, since the embedded portion being the semiconductor material is removed, the difference of the the refractive indexes of the core (active layer, absorption layer) and the cladding becomes large, thereby the expansion of the light confinement mode in the vertical direction is increased.

Therefore, in order to prevent the light radiation to the substrate side, the deeper mesa waveguide than the mesa waveguide processing at the first time is processed. This depth varies depending on the design of the waveguide, but it is normally processed to be 0.1 to 10 μm deeper than the bottom surface of the waveguide formed at the first time. According to this embodiment, it is processed 2 μm deep. By this second processing, the SSC 20 having the enlarged tapered portion and the reduced tapered portion can be formed. By the way, the distance between the tapered portions is determined so that the straight portion 20B between the enlarged tapered portion 20A and the reduced tapered portion 20C is formed at 20 μm or more.

Since the wavelength of the absorption spectrum approaches the laser wavelength according to the applied voltage by quantum confinement Stark effect in the EA portion 12 integrated with the laser portion 11 via the SSC 20, the laser element provided with the EA portion 12 integrated with the laser portion 11 via the SSC 20 can be applied to the optical transmitter capable of converting the electric signal into the ON/OFF signal of the light signal by changing the amount of the light absorption through the voltage control.

1. A semiconductor laser comprising:
a laser having an active region for injecting a current to produce an optical gain; a modulator for changing an absorption coefficient by applying a voltage; and a spot size converter for combining an enlarged taper and a reduced taper, which are monolithically integrated on a same substrate, wherein
the spot size converter is disposed between a laser region of the laser and an absorption region of the modulator.

2. A semiconductor laser comprising:
a laser having an active region for injecting a current to produce an optical gain; a first spot size converter for combining an enlarged taper and a reduced taper; a modulator for changing an absorption coefficient by applying an electric signal; a second spot size converter for combining an enlarged taper and a reduced taper; and a semiconductor optical amplifier, which are monolithically integrated on a same substrate, wherein
the first spot size converter is disposed between a laser region of the laser and a modulator region, and the second spot size converter is disposed between the modulator and the semiconductor optical amplifier.

3. The semiconductor laser according to claim 1, wherein the spot size converter is optically connected in the order of an enlarged taper, a straight waveguide, and a reduced taper, and is composed of these elements.

4. The semiconductor laser according to claim 1, wherein each aspect ratio of two tapers included in the spot size converter is the same, and a straight waveguide region is within 20 to 100 μm.

5. The semiconductor laser according to claim 1, wherein the semiconductor laser is processed by twice of mesa processing, with height of mesa processed by the first processing being different from height of mesa processed by the second processing, and a depth of second mesa processing is deeper than that of a bottom surface of the first mesa processing by about 0.1 to 10 μm.

6. An optical transmitter to which the semiconductor laser according to claim 1 including the laser region, the modulator region, and the spot size converter is applied, and which converts an electric signal into an optical signal by changing an amount of a light absorption through a voltage control.
